(19) United States
(12) Patent Application Publication
(10) Pub. No.: US 2008/0061364 A1
(43) Pub. Date: Mar. 13, 2008

(54) Trench type MOS transistor and method for manufacturing the same

(75) Inventors: Gyu Gwang Sim, Gunpo-si (KR); Jong Min Kim, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU HITEK CO., LTD.

(21) Appl. No.: 11/898,296

(22) Filed: Sep. 11, 2007

(30) Foreign Application Priority Data
Sep. 12, 2006 (KR) 10-2006-0087747

(51) Int. Cl. H01L 29/78; H01L 21/336

(52) U.S. Cl. 257/330; 438/270; 257/E21.41; 257/E29.262

(57) ABSTRACT

A trench type MOS transistor and a method for manufacturing the trench type MOS transistor are disclosed. In one aspect, the total capacitance between a gate electrode and a drain region of the trench type MOS transistor can be reduced. In particular, a PN junction is formed in the gate electrode to reduce the total capacitance between the gate electrode and the drain region.

This application claims the benefit of priority from Korean Patent Application No. 10-2006-0087747, filed on Sep. 12, 2006, the entire contents of which are incorporated herein by reference.

### BACKGROUND

1. Technical Field

The present invention relates to a semiconductor device, and more particularly, to a trench type metal-oxide-semiconductor (MOS) transistor and a method for manufacturing the trench type MOS transistor.

2. Related Art

FIGS. 1A and 1B are cross-sectional views of conventional trench type MOS transistors.

Referring to FIG. 1A, a conventional trench type MOS transistor includes a semiconductor substrate 100, a drain region 101 disposed on semiconductor substrate 100, a drift region 102 formed on drain region 101, a channel body 103 formed on drift region 102, and a source region 104 formed on channel body 103. Drain region 101 may be implanted with a high-concentration N-type dopant. Drift region 102 may be implanted with a low-concentration N-type dopant. Channel body 103 may be implanted with a P-type dopant. Source region 104 may be implanted with an N-type dopant.

The structure may be etched to a predetermined depth to form a trench. For example, the structure may be etched to a depth, such that a portion of drift region 102 is exposed, thereby forming the trench. Subsequently, a gate oxide film 106 is formed on inner walls of the trench.

Thereafter, a polysilicon layer may be filled in the trench to form a gate electrode 105. For example, an N-type dopant may be implanted into the polysilicon layer to form gate electrode 105.

In the trench type MOS transistor shown in FIG. 1A, a capacitance generated in a region 107 between drain region 101 and gate electrode 105 due to the polysilicon layer filled in the trench. The capacitance may hinder a high-speed operation and may cause, for example, the Miller effect.

As shown in FIG. 1B, a gate oxide film 106a is formed in the trench to have a greater thickness at the bottom portion of the trench. That is, the trench type MOS transistor shown in FIG. 1B includes gate oxide film 106a, which is formed to have a thickness in a region 108 between gate electrode 105 and drain region 101. The thickness of gate oxide film 106a in region 108 (as shown in FIG. 1B) is greater than the thickness of gate oxide film 106 in region 107 (as shown in FIG. 1A).

### SUMMARY

Accordingly, the present invention is directed to a trench type MOS transistor and a method for manufacturing the trench type MOS transistor.

In an embodiment consistent with the present invention, there is provided a trench type MOS transistor capable of reducing the capacitance between a gate electrode and a drain region.

In another embodiment consistent with the present invention, there is provided a trench type MOS transistor capable of reducing the total capacitance between a gate electrode and a drain region by forming a PN junction in the gate electrode formed of polysilicon.

According to an embodiment of the present invention, a trench type MOS transistor includes a semiconductor substrate; a drain region formed on the semiconductor substrate, the drain region being implanted with a first type dopant; a drift region formed on the drain region, the drift region being implanted with the first conductivity-type dopant; a channel body formed on the drift region, the channel body being implanted with a second conductivity-type dopant; a source region formed in the channel body, the source region being implanted with the first conductivity-type dopant; a trench formed by etching the source region, the channel body and a portion of the drift region; a gate insulating film formed on inner walls of the trench; and a polysilicon gate electrode formed in the trench and on the gate insulating film, the polysilicon gate electrode having a lower portion implanted with the first conductivity-type dopant and an upper portion implanted with the second conductivity-type dopant, the upper and lower portions forming a junction therebetween.

For example, the drain region may comprise a high-concentration N-type dopant implanted thereinto, the drift region may comprise a low-concentration N-type dopant implanted thereinto, the channel body may comprise a P-type dopant implanted thereinto, and the source region may comprise an N-type dopant implanted thereinto.

For example, the polysilicon gate electrode may include a PN junction between a region into which a P-type dopant is implanted and a region into which an N-type dopant is implanted.

For example, the polysilicon gate electrode may include a first polysilicon portion comprising an N-type dopant and a second polysilicon portion comprising a P-type dopant. The second polysilicon portion may be formed below the first polysilicon portion.

For example, the junction between the upper and lower portions of the polysilicon gate electrode may be aligned with or lower than a junction between the drift region and the channel body.

In another embodiment consistent with the present invention, a method for manufacturing a trench type MOS transistor includes forming a drain region implanted with a first conductivity-type dopant of a high concentration on a semiconductor substrate, forming a drift region implanted with the first conductivity-type dopant of a low concentration on the drain region, and forming a channel body implanted with a second conductivity-type dopant on the drift region; etching the channel body and a portion of the drift region so as to form a trench; forming a gate insulating film on inner walls of the trench; forming a polysilicon gate electrode in the trench, the polysilicon gate electrode having a lower portion implanted with a first conductivity-type dopant and an upper portion implanted with a second conductivity-type dopant, the lower portion and the upper portion forming a junction therebetween; and forming a source region in the channel body located at both sides of the polysilicon gate electrode.

For example, the first conductivity-type dopant may include an N-type dopant and the second conductivity-type dopant may include a P-type dopant.

For example, the junction of the polysilicon gate electrode may include a PN junction.

For example, forming the polysilicon gate electrode may include forming, in the lower portion of the trench, a lower polysilicon layer implanted with a P-type dopant; and forming, in the upper portion of the trench, an upper polysilicon layer implanted with an N-type dopant. Here, the junction between the lower and upper portions of the polysilicon layer may be formed at a position aligning with or lower than a junction between the drift region and the channel body.

For example, forming the polysilicon gate electrode may include forming in the trench a polysilicon layer doped with a P-type dopant; etching the polysilicon layer to a predetermined depth to form a lower polysilicon layer; and forming an upper polysilicon layer doped with an N-type dopant in the trench and on the lower polysilicon layer. Here, the junction between the lower and upper portions of the trench may be aligned with or lower than a junction between the drift region and the channel body.

For example, forming the polysilicon gate electrode may include filling a polysilicon material in the trench; implanting a P-type dopant into the filled polysilicon material to form a polysilicon layer; and implanting an N-type dopant into the polysilicon layer up to a predetermined depth, thereby forming a boundary in the polysilicon layer. Here, the boundary may be aligned with or lower than a junction between the drift region and the channel body.

It is to be understood that both the foregoing general description and the following detailed description consistent with the present invention are exemplary and explanatory, and are intended to provide further explanation of the invention as claimed.

### BRIEF DESCRIPTION OF THE DRAWINGS

In the drawings:

FIGS. 1A and 1B are cross-sectional views of conventional trench type MOS transistors;

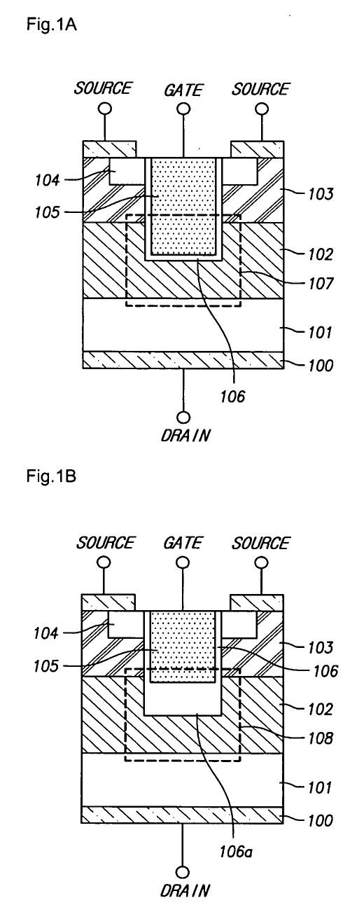

FIG. 2 is a cross-sectional view of a trench type MOS transistor according to an embodiment consistent with the present invention; and

FIGS. 3A to 3D are cross-sectional views of a method for manufacturing a trench type MOS transistor according to an embodiment consistent with the present invention.

### DETAILED DESCRIPTION

Hereinafter, a trench type MOS transistor and a method for manufacturing the trench type MOS transistor, according to an embodiment consistent with the present invention, will be described with reference to the accompanying drawings.

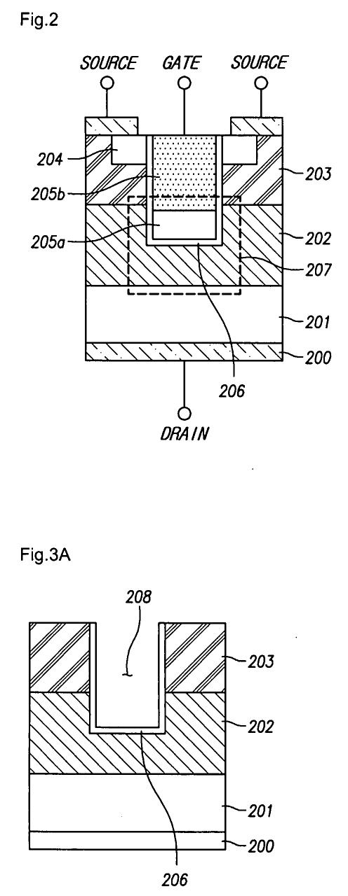

Referring to FIG. 2, the trench type MOS transistor includes a semiconductor substrate 200, a drain region 201 formed on semiconductor substrate 200, a drift region 202 formed on drain region 201, a channel body 203 formed on drift region 202, and a source region 204 formed in channel body 203. Source region 204, channel body 203, and drift region 202 may be etched to form a trench, thereby exposing a portion of drift region 202. The trench type MOS transistor further includes a gate insulating film 206 formed on inner walls of the trench, a gate electrode lower region 205a formed in a lower portion of the trench and on gate insulating film 206, and a gate electrode upper region 205b formed in the trench and on lower region 205a. In one embodiment, gate electrode lower region 205a and upper region 205b may comprise polysilicon. Polysilicon regions 205a and 205b may be doped with different dopants. Hereinafter, gate electrode regions 205a and 205b may alternatively be referred to as polysilicon gate electrode regions 205a and 205b.

Hereinafter, N-type is referred to as a first conductivity-type and P-type is referred to as a second conductivity-type.

Drain region 201 is formed on semiconductor substrate 200, and the first conductivity-type dopant may be implanted into drain region 201. For example, the first conductivity-type dopant of a high concentration may be ion-implanted into drain region 201.

Drift region 202 is formed on drain region 201, and the first conductivity-type dopant may be implanted into drift region 202. For example, the first conductivity-type dopant of a low concentration may be ion-implanted into drift region 202.

Channel body 203 is formed on drift region 202, and the second conductivity-type dopant may be implanted into channel body 203.

Source region 204 is formed in channel body 203, and the first conductivity-type dopant may be implanted into source region 204.

After source region 204 is formed, an etching process may be performed from source region 204 up to a portion of drift region 202, such that a trench is formed. Subsequently, a gate insulating film 206 is formed on inner walls of the trench. For example, gate insulating film 206 may be formed by a thermal oxidation process.

A gate electrode having a PN junction structure, according to an embodiment consistent with the present invention, may be formed in the trench, in which gate insulating film 206 is formed.

The gate electrode may include first polysilicon portion 205b doped with the first conductivity-type dopant and second polysilicon portion 205a doped with the second conductivity-type dopant. As a result, the gate electrode may form a PN junction.

Here, a total capacitance generated in a region 207 between the gate electrode and drain region 201 may be a serial connection of a first capacitance formed by the PN junction between first polysilicon portion 205b and second polysilicon portion 205a and a second capacitance formed by gate insulating film 206 at the lower portion of the trench.

Accordingly, because the gate electrode includes the PN junction, the total capacitance between the gate electrode and drain region 201 is reduced. As a result, a high-speed operation is possible.

In particular, in order to reduce the total capacitance between the gate electrode and drain region 201, the PN junction between polysilicon gate electrode regions 205a and 205b should be formed at a position aligning with or lower than the PN junction between drift region 202 and channel body 203.

That is, the gate electrode is formed such that the boundary between drift region 202 and channel body 203 is higher than the boundary between first polysilicon portion 205b and second polysilicon portion 205a.

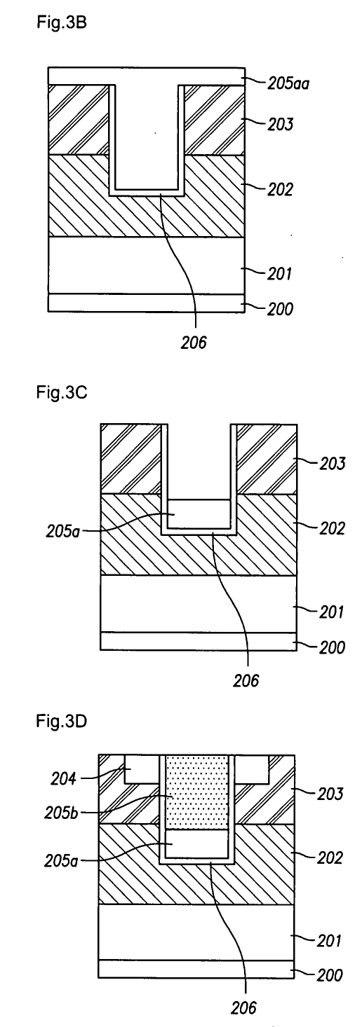

Next, a method for manufacturing the trench type MOS transistor, according to an embodiment consistent with the present invention, will be described with reference to FIGS. 3A to 3D.

First, as shown in FIG. 3A, drain region 201 is formed on semiconductor substrate 100. In one embodiment, drain region 201 may be implanted with the first conductivity-type dopant of a high concentration.

Drift region 202 is formed on drain region 201. In one embodiment, drift region 202 may be implanted with the first conductivity-type dopant of a high concentration.

Channel body 203 is formed on drift region 202. In one embodiment, channel body 203 may be implanted with the second conductivity-type dopant.

Drain region 201, drift region 202, and channel body 203 may be sequentially formed using an ion implantation process and a silicon epitaxial process.

Then, the resultant structure is etched through channel body 203 to a predetermined depth to form a trench 208. In one embodiment, the resultant structure may be etched from a top surface of channel body 203 to a middle portion of drift region 202, such that trench 208 of the predetermined depth is formed.

Gate insulating film 206 may be formed on the inner walls of trench 208 using a thermal oxidation process.

As shown in FIG. 3B, a polysilicon layer 205aa, which may be implanted with the second conductivity-type dopant, is deposited on the top surface of channel body 203 and in trench 208. At this time, polysilicon layer 205aa fills trench 208 completely.

Thereafter, as shown in FIG. 3C, a portion of the deposited polysilicon layer 205aa is etched. At this time, a polysilicon layer 205a having a predetermined height remains in the lower portion of trench 208. That is, a portion of polysilicon 205aa deposited in the lower portion of trench 208 remains in trench 208 and has a predetermined thickness. The remaining polysilicon becomes second polysilicon layer 205a.

However, an upper surface of polysilicon layer 205a should be aligning with or lower than the PN junction between channel body 203 and drift region 202. That is, when the deposited polysilicon 205aa is partially etched, the polysilicon is etched down to a position in drift region 202 deeper than that of channel body 203.

Then, as shown in FIG. 3D, polysilicon layer 205b, which is doped with the first conductivity-type dopant, is deposited to fill trench 208, using a deposition method.

Thereafter, the first conductivity-type dopant is implanted into channel body 203 at both sides of polysilicon gate electrode regions 205a and 205b to form source region 204.

As a result, the trench type MOS transistor having the PN junction shown in FIG. 2 is manufactured.

A method for forming the polysilicon gate electrode having the PN junction in trench 208, according to another embodiment consistent with the present invention, will now be described.

In the above-described method, polysilicon regions 205a and 205b implanted with different dopants are filled in trench 208 using a deposition method.

However, in this embodiment, a polysilicon material without being doped may fill in trench 208, and then the second conductivity-type dopant may be implanted into the polysilicon material to form a polysilicon layer.

Next, the first conductivity-type dopant is ion-implanted into the buried polysilicon layer up to a predetermined depth.

In one embodiment, the first conductivity-type dopant may be implanted in the filled polysilicon layer to a depth corresponding to a position in drift region 202 deeper than that of channel body 203. As a result, the ion implantation depth of the second conductivity-type dopant may be appropriately controlled, such that the boundary between the region into which the second conductivity-type dopant is implanted and the region into which the first conductivity-type dopant is implanted is aligning with or lower than the PN junction between channel body 203 and drift region 202.

Consistent with the present invention, because a polysilicon gate electrode of a trench type MOS transistor includes a PN junction, total capacitance between a gate electrode and a drain region can be reduced.

Accordingly, the trench type MOS transistor consistent with the present invention can achieve a high-speed operation.

It will be apparent to those skilled in the art that various modifications and variations can be made without departing from the spirit or scope of the invention. Thus, it is intended that the present invention covers such modifications and variations provided they fall within the scope of the appended claims and their equivalents.

What is claimed is:

1. A trench type metal-oxide-semiconductor (MOS) transistor comprising:
a semiconductor substrate;
a drain region formed on the semiconductor substrate, the drain region including a first conductivity-type dopant;
a drift region formed on the drain region, the drift region including the first conductivity-type dopant;
a channel body formed on the drift region, the channel body including a second conductivity-type dopant;
a source region formed in the channel body, the source region including the first conductivity-type dopant;
a trench formed by etching the source region, the channel body, and a portion of the drift region;
a gate insulating film formed on inner walls of the trench; and
a polysilicon gate electrode formed on the gate insulating film, the polysilicon gate electrode having a lower portion including a first conductivity-type dopant and an upper portion including a second conductivity-type dopant, the upper and lower portions forming a junction therebetween.

2. The trench type MOS transistor according to claim 1, wherein the drain region comprises a high-concentration N-type dopant implanted thereinto.

3. The trench type MOS transistor according to claim 1, wherein the drift region comprises a low-concentration N-type dopant implanted thereinto.

4. The trench type MOS transistor according to claim 1, wherein the channel body comprises a P-type dopant implanted thereinto.

5. The trench type MOS transistor according to claim 1, wherein the source region comprises an N-type dopant implanted thereinto.

6. The trench type MOS transistor according to claim 1, wherein the junction between the upper and lower portions of the polysilicon gate electrode comprises a PN junction.

7. The trench type MOS transistor according to claim 1, wherein the upper portion of the polysilicon gate electrode includes an N-type dopant and the lower portion of the polysilicon gate electrode includes a P-type dopant.

8. The trench type MOS transistor according to claim 1, wherein the junction between the upper and lower portions is aligned with a junction between the drift region and the channel body.

9. The trench type MOS transistor according to claim 1, wherein the junction between the upper and lower portions is lower than a junction between the drift region and the channel body.

10. A method for manufacturing a trench type MOS transistor, comprising:
forming a drain region implanted with a first conductivity-type dopant of a high concentration on a semiconductor substrate, forming a drift region implanted with the first conductivity-type dopant of a low concentration on the drain region, and forming a channel body implanted with a second conductivity-type dopant on the drift region;
etching the channel body and a portion of the drift region so as to form a trench;
forming a gate insulating film on inner walls of the trench;
forming a polysilicon gate electrode on the gate insulating film, the polysilicon gate electrode having a lower portion implanted with the first conductivity-type dopant and an upper portion implanted with the second conductivity-type dopant, the lower portion and the upper portion forming a junction therebetween; and
forming a source region in the channel body located at both sides of the polysilicon gate electrode.

11. The method according to claim 10, wherein the first conductivity-type dopant comprises an N-type dopant and the second conductivity-type dopant comprises a P-type dopant.

12. The method according to claim 10, wherein the junction formed in the polysilicon gate electrode includes a PN junction.

13. The method according to claim 10, wherein forming the polysilicon gate electrode further comprises:
forming, in the lower portion of the trench, a lower polysilicon layer implanted with a P-type dopant; and
forming, in the upper portion of the trench, an upper polysilicon layer implanted with an N-type dopant.

14. The method according to claim 13, wherein the junction between the lower and upper portions of the trench is formed at a position aligned with or lower than a junction between the drift region and the channel body.

15. The method according to claim 10, wherein forming the polysilicon gate electrode further comprises:
forming a polysilicon layer doped with a P-type dopant in the trench;
etching the polysilicon layer to a predetermined depth to form a lower polysilicon layer; and
forming an upper polysilicon layer doped with an N-type dopant on the lower polysilicon layer.

16. The method according to claim 15, wherein an upper surface of the lower polysilicon layer is aligned with or lower than a junction between the drift region and the channel body.

17. The method according to claim 10, wherein forming the polysilicon gate electrode further comprises:
filling a polysilicon material in the trench;
implanting a P-type dopant into the filled polysilicon material to form a polysilicon layer; and
implanting an N-type dopant into the polysilicon layer up to a predetermined depth, thereby forming a boundary in the polysilicon layer.

18. The method according to claim 17, wherein the boundary is aligned with or lower than a position of a junction between the drift region and the channel body.
